(19) United States
(12) Patent Application Publication
(10) Pub. No.: US 2019/0140017 A1
(43) Pub. Date: May 9, 2019

(54) MICRO LED COLOR DISPLAY DEVICE

(71) Applicant: Shenzhen China Star Optoelectronics Technology Co., Ltd., Shenzhen City (CN)

(72) Inventors: Lixuan Chen, Shenzhen City (CN); Yungjui Lee, Shenzhen City (CN)

(21) Appl. No.: 16/241,992

(22) Filed: Jan. 8, 2019

Related U.S. Application Data
(63) Continuation-in-part of application No. 15/548,099, filed on Aug. 2, 2017.

(30) Foreign Application Priority Data
Jun. 13, 2017 (CN) 201710443800.4

(51) Int. Cl. H01L 27/15; H01L 33/50

(52) U.S. Cl. CPC H01L 27/156; H01L 33/507; H01L 33/505

(57) ABSTRACT

A Micro LED color display device is provided, which uses a second blue LED (B2) with a short wavelength to excite a green-color-conversion layer (G) to replace a green LED (P2) in green sub-pixels. The second blue LED (B2) itself is more stable, the chromaticity of the green color is controlled by controlling the accuracy of the coating thickness of the green-color-conversion layer (G). The accuracy of the coating thickness is easily controlled than the specification of the green LED, and hence, the chromaticity uniformity is better, the stability of the green color is easy to control, and the display quality is improved.

### CROSS REFERENCE TO RELATED APPLICATIONS

This is a continuation-in-part application of co-pending patent application Ser. No. 15/548,099, filed on Aug. 2, 2017, which is a national stage of PCT Application Number PCT/CN2017/092859, filed on Jul. 13, 2017, claiming foreign priority of Chinese Patent Application Number 201710443800.4, filed on Jun. 13, 2017.

### BACKGROUND OF THE INVENTION

### Field of Invention

The present invention relates to the field of liquid crystal display, and more particularly to a Micro LED color display device.

### Description of Prior Art

With the rapid development of wearable display devices, there is the micro-light-emitting diodes (Micro LED, uLED) technology. The Micro LED technology, in other words, LED miniaturization and matrix technology, refers to a high-density small size LED array integrated on a chip. The power consumption of thee Micro LED is much smaller than the liquid crystal display (LCD), the Micro LED and the organic light-emitting diode (OLED) are both self-luminous, the distance between the pixels of the Micro LED can be downsized from the millimeter level to the micrometer level, the color saturation of the Micro LED is close to that of the OLED, hence, many manufacturers has taken the Micro LED as the next generation of display.

Conventionally, the Micro LED array is manufactured by the Micro Transfer Print method: after the LED bare chip is separated from the sapphire substrate by laser lift-off (LLO) technology, the LED bare chip is absorbed from a supply substrate by using a patterned transfer layer and transferred to a receiving substrate. Specifically, the receiving substrate is a silicon substrate with a prepared circuit pattern in advance. By aligning the transfer substrate with the receiving substrate, the LED bare chip adsorbed on the transfer layer is attached to a mating position of the receiving substrate, then the transfer layer is lift-off, the transfer of LED bare chip is completed. Various patents such as US2013/0210194, US2013/0128585 and the like have been described in detail with respect to Micro Transfer Print techniques.

The Micro LED color display device can be manufactured by the LED array manufactured in an integrated circuit, after a LED display driving circuit is manufactured by the normal CMOS integrated circuit manufacturing process. In the actual production process of LED, there is a process of binning the specifications to the LEDs (industry called Bin), in different Bins, the peak wavelength will move, LED color, brightness, etc. will have a problem of consistent deviation. Making of Micro LED color display devices with LED as the light source requires large-scale production of red, green, and blue LEDs. In this process, due to the fact that the LEDs grow on different wafers (Wafer) are possibly in different Bin. Thus, the chromaticity of LED deviations is an inevitable phenomenon.

Please refer to FIG. 1, which is found that the chromaticity difference of the green LED is the largest for the adjacent 3 to 4 Bin LEDs: when the peak wavelength is shifted by 2 nm, the x-chromaticity difference of the green LED G Δ X exceeds 0.01, and a range of one Bin's peak wavelength is often 2.5 nm, which means that for the Micro LED color display device, the stability of the green color is not easy to control, green color chromaticity uniformity needs to be improved.

### SUMMARY OF THE INVENTION

An object of the present invention is to provide a Micro LED color display device, which has good color uniformity, and the green color stability is easy to control, to improve the display quality.

In order to complete the object, the present invention provides a Micro LED color display device, which comprises a driving substrate, a package substrate disposed opposite to the driving substrate, a plurality of blue sub-pixels, green sub-pixels, and red sub-pixels arranged in an array arrangement between the driving substrate and the package substrate, and a support disposed between the driving substrate and the package substrate. An LED is disposed in each of the sub-pixels.

The blue sub-pixels comprise a first bottom-pixel electrode disposed on the driving substrate, a first top-pixel electrode disposed opposite to the first bottom-pixel electrode, and a first blue LED interposed between the first bottom-pixel electrode and the first top-pixel electrode. The green sub-pixels comprise a second bottom-pixel electrode disposed on the driving substrate, a second top-pixel electrode disposed opposite to the second bottom-pixel electrode, a second blue LED interposed between the second bottom-pixel electrode and the second top-pixel electrode, and a green-color-conversion layer interposed between the second top-pixel electrode and the package substrate. The red sub-pixels comprise a third bottom-pixel electrode disposed on the driving substrate, a third top-pixel electrode disposed opposite to the third bottom-pixel electrode, and a LED interposed between the third bottom-pixel electrode and the third top-pixel electrode.

Optionally, in the red sub-pixel, the LED interposed between the third bottom-pixel electrode and the third top-pixel electrode is a red LED.

Optionally, in the red sub-pixels, the LED interposed between the third bottom-pixel electrode and the third top-pixel electrode is a third blue LED; the red sub-pixels further comprise a red-color-conversion layer interposed between the third top-pixel electrode and the package substrate.

The blue sub-pixels further comprise a first transparent spacer disposed between the first top-pixel electrode and the package substrate, and the red sub-pixels further comprises a second transparent spacer disposed between the third top-pixel electrode and the package substrate.

The blue sub-pixels further comprise a first transparent spacer disposed between the first top-pixel electrode and the package substrate.

The green-color-conversion layer is selected from green quantum dots.

The red-color-conversion layer is selected from red quantum dots.

A height of the first transparent spacer and a height of the second transparent spacer are the same or different, a sum of heights of the first blue LED and the first transparent spacer and a sum of heights of the red LED and the second transparent spacer are the same.

A height of the first top-pixel electrode and a height of the third top-pixel electrode are the same or different; a sum of heights of the first bottom-pixel electrode, the first blue LED, and the first top-pixel electrode is the same as an interval between the driving substrate and the package substrate; a sum of heights of the third bottom-pixel electrode, the red LED, and the third top-pixel electrode is the same as the interval between the driving substrate and the package substrate.

The package substrate is selected from a group consisting of polyethylene terephthalate, polycarbonate, and glass.

The support is selected from a group consisting of an organic photoresist and silicon ball.

The first transparent spacer and the second transparent spacer are all selected from a group consisting of organic transparent materials and inorganic transparent materials.

The first, second, and third top-pixel electrodes, and the first, second, and third bottom-pixel electrodes are selected from a group consisting of indium tin oxide, and conductive metal.

The present invention further provides a Micro LED color display device, which comprises a driving substrate, a package substrate disposed opposite to the driving substrate, a plurality of blue sub-pixels, green sub-pixels, and red sub-pixels arranged in an array arrangement between the driving substrate and the package substrate, and a support disposed between the driving substrate and the package substrate. An LED is disposed in each of the sub-pixels.

The blue sub-pixels comprise a first bottom-pixel electrode disposed on the driving substrate, a first top-pixel electrode disposed opposite to the first bottom-pixel electrode, and a first blue LED interposed between the first bottom-pixel electrode and the first top-pixel electrode. The green sub-pixels comprise a second bottom-pixel electrode disposed on the driving substrate, a second top-pixel electrode disposed opposite to the second bottom-pixel electrode, a second blue LED interposed between the second bottom-pixel electrode and the second top-pixel electrode, and a green-color-conversion layer interposed between the second top-pixel electrode and the package substrate. The red sub-pixels comprise a third bottom-pixel electrode disposed on the driving substrate, a third top-pixel electrode disposed opposite to the third bottom-pixel electrode, and a LED interposed between the third bottom-pixel electrode and the third top-pixel electrode.

In the red sub-pixel, the LED interposed between the third bottom-pixel electrode and the third top-pixel electrode is a red LED.

The blue sub-pixels further comprise a first transparent spacer disposed between the first top-pixel electrode and the package substrate, and the red sub-pixels further comprises a second transparent spacer disposed between the third top-pixel electrode and the package substrate.

The green-color-conversion layer is selected from green quantum dots.

A height of the first transparent spacer and a height of the second transparent spacer are the same or different, a sum of heights of the first blue LED and the first transparent spacer and a sum of heights of the red LED and the second transparent spacer are the same.

The beneficial effects of the present invention is: the invention provides a Micro LED color display device which uses the second blue LED with a short wavelength to excite the green-color-conversion layer to replace the green LED in the green sub-pixels, the second blue LED itself is more stable, the chromaticity of the green color is controlled by controlling the accuracy of the coating thickness of the green-color-conversion layer. The accuracy of the coating thickness is easily controlled than the specification of the green LED, hence, the chromaticity uniformity is better, the stability of the green color is easy to control, and the display quality is improved.

### BRIEF DESCRIPTION OF THE DRAWINGS

For better understanding the technical proposals and other beneficial effects of the present invention, please refer the following detailed description of the present invention with the accompanying drawings.

In drawings:

FIG. 1 is an illustrative curved-relationship diagram when the chromaticities of pure colors are shifted with the peak wavelength of the LED.

FIG. 2 is a schematic structural view of a first embodiment of the Micro LED color display device of the present invention.

FIG. 3 is a schematic structural view of a second embodiment of the Micro LED color display device of the present invention.

FIG. 4 is a schematic structural view of a third embodiment of the Micro LED color display device of the present invention.

FIG. 5 is a schematic view showing a green-color-conversion layer made by an ink jet printing method.

### DETAILED DESCRIPTION OF THE PREFERRED EMBODIMENTS

The technical proposals and the effects of the present invention will be described in further detail with reference to the below preferred embodiments of the present invention and their accompanying drawings.

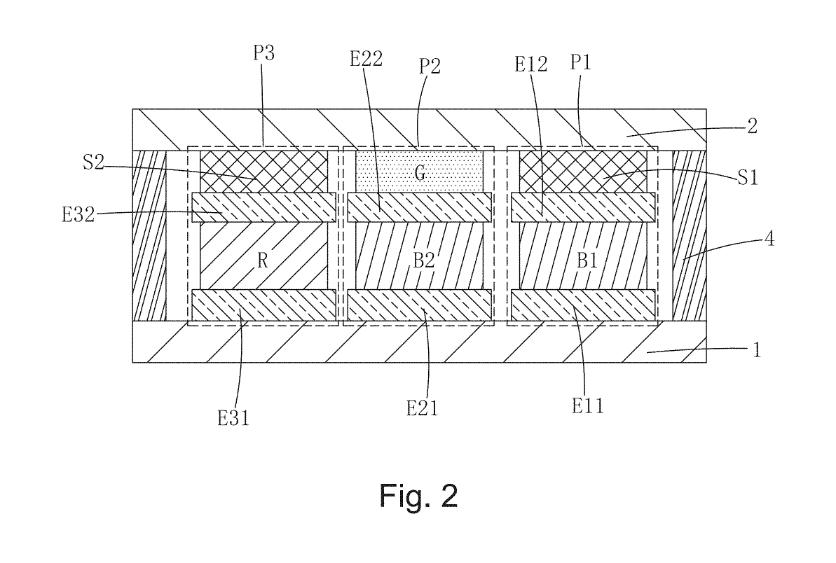

The present invention provides a Micro LED color display device. FIG. 2 is a first embodiment of the present invention, which comprises a driving substrate 1, a package substrate 2 disposed opposite to the driving substrate 1, a plurality of blue sub-pixels P1, green sub-pixels P2, and red sub-pixels P3 arranged in an array arrangement between the driving substrate 1 and the package substrate 2, and a support 4 disposed between the driving substrate 1 and the package substrate 2.

The blue sub-pixels P1 comprise a first bottom-pixel electrode E11 disposed on the driving substrate 1, a first top-pixel electrode E12 disposed opposite to the first bottom-pixel electrode E11, a first blue LED B1 interposed between the first bottom-pixel electrode E11 and the first top-pixel electrode E12, and a first transparent spacer S1 disposed between the first top-pixel electrode E12 and the package substrate 2. The green sub-pixels P2 comprise a second bottom-pixel electrode E21 disposed on the driving substrate 1, a second top-pixel electrode E22 disposed opposite to the second bottom-pixel electrode E21, a second blue LED B2 (which may emit light of a wavelength different from, such as being shorter than, a wavelength of light emitting from the first blue LED B1) interposed between the second bottom-pixel electrode E21 and the second top-pixel electrode E22, and a green-color-conversion layer G interposed between the second top-pixel electrode E22 and the package substrate 2. The red sub-pixels P3 comprise a third bottom-pixel electrode E31 disposed on the driving substrate 1, a third top-pixel electrode E32 disposed opposite to the third bottom-pixel electrode E31, a red LED R interposed between the third bottom-pixel electrode E31 and the third top-pixel electrode E32, and a second transparent spacer S2 disposed between the third top-pixel electrode E32 and the package substrate 2.

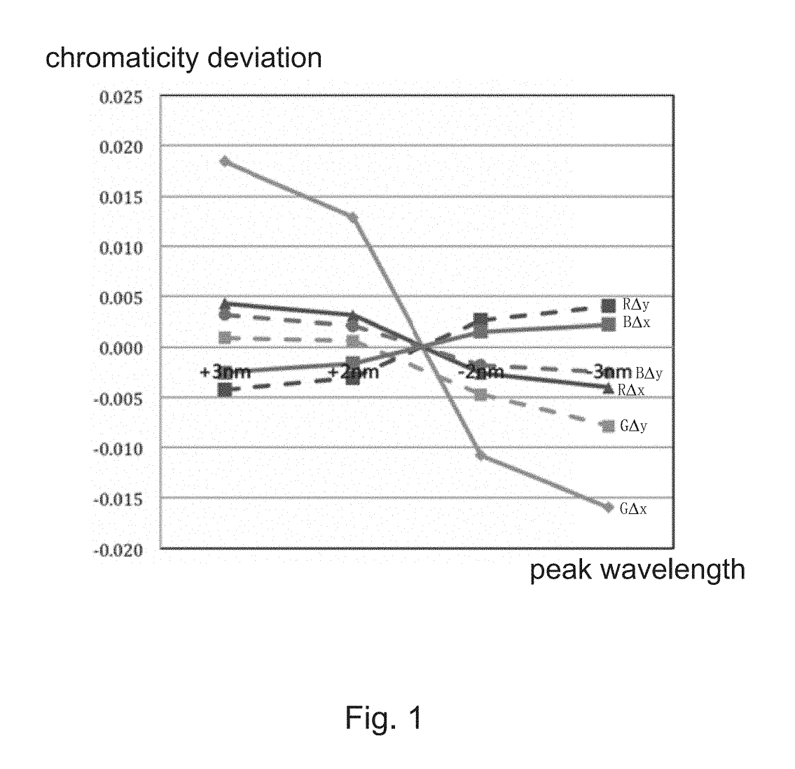

In the first embodiment of the Micro LED color display device of the present invention, the blue sub-pixel P1 directly emits blue color light with the first blue LED B1, the red sub-pixel P3 directly emits red color light with the red LED R, with FIG. 1, the first blue LED B1 and red LED R both have smaller chromaticity difference with respect to the offset of the peak wavelength, in other words, the optical differences of the first blue LED B1 and red LED R are not large, so the first blue LED B1 and red LED R themselves have relatively uniform chromaticity. The difference between the present invention and the conventional art is: the second blue LED B2 with a short wavelength is used to excite the green-color-conversion layer G to replace the green LED, the second blue LED itself is more stable, the chromaticity of the green color is controlled by controlling the accuracy of the coating thickness of the green-color-conversion layer. The accuracy of the coating thickness is easily controlled than the Bin of the green LED, hence, the chromaticity uniformity is better, the stability of the green color is easy to control, and the display quality is improved.

Specifically:

The green-color-conversion layer G is selected from green quantum dots, which are able to be excited by blue light to emit green light. The green-color-conversion layer G is coated on the package substrate 2.

The driving substrate 1 is provided with a display driving circuit (not shown) for controlling the switching and brightness of the LED within each sub-pixel by a thin film transistor (TFT) array.

The package substrate 2 can be plastic with a certain hardness, such as polyethylene terephthalate (PET) or polycarbonate (PC), or glass.

The first, second, and third top-pixel electrodes E12, E22, E32, and the first, second, and third bottom-pixel electrodes E11, E21, E31 are selected from a group consisting of indium tin oxide (ITO), and conductive metal, such as Silver (Ag).

The support 4 is used to maintain a constant pitch between the driving substrate 1 and the package substrate 2 and to prevent the green-color-conversion layer G from being pressed by the second blue LED B2, and even if the support 4 is subjected to compressive deformation, the green-color-conversion layer G should not be compressive to have a height variation, in other words, a film thickness variation. Furthermore, the support 4 may be made by the organic photoresist which is used to form the Photo spacers in the LCD, or harder silicon ball and so on.

The first transparent spacer S1 and the second transparent spacer S2 are disposed so that the first top-pixel electrode E12, the second top-pixel electrode E22, and the third top-pixel electrode E32 are at the same height, then, the first blue LED B1, the second blue LED B2, and the red LED R are relatively uniform in heights. Furthermore, the materials of the first transparent spacers S1 and the second transparent spacers S2 are organic transparent materials such as Polyfluoroalkoxy resin (PFA), or inorganic transparent material. In consideration of the fact that the green-color-conversion layer G is coated on the package substrate 2, it is preferable to choose a more uniform process to manufacture the green-color-conversion layer G when manufacturing the first transparent spacer S1 and the second transparent spacer S2.

The LEDs R, B1, B2 may be of the same sizes, such as heights, or alternatively, they may be of different sizes, such as heights. The heights of the first transparent spacer S1 and the second transparent spacer S2 may be the same or different, as long as a sum of the heights of the first blue LED B1 and the first transparent spacer S1 and a sum of the heights of the red LED R and the second transparent spacers S2 are ensured to be relatively uniform, so that the heights (film thickness) of the first top-pixel electrode E12 and the third top-pixel electrode E32 are uniform.

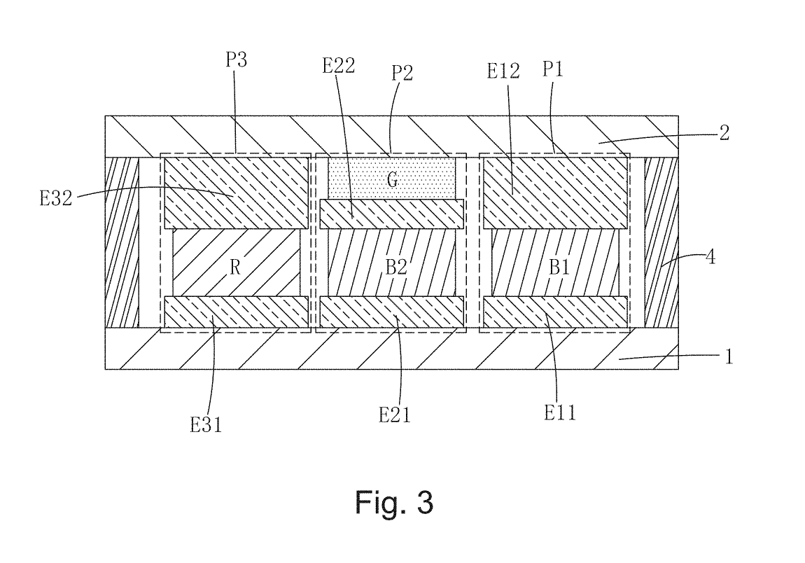

FIG. 3 shows a second embodiment of the Micro LED color display device of the present invention. The difference between the second embodiment and the first embodiment is: the first transparent spacer S1 is omitted, and the first top-pixel electrode E12 is directly contacted with the package substrate 2; the second transparent spacer S2 is omitted, and the third top-pixel electrode E32 is directly contacted with the package substrate 2. The other structures are unchanged and are not described here repeatedly.

Furthermore, the heights (film thickness) of the first top-pixel electrode E12 and the third top-pixel electrode E32 can be the same or different, as long as the film thicknesses of corresponding pixel electrode with respect to the different sub-pixels are controlled by the mask when manufacturing each pixel electrodes, to ensure that a sum of the heights of the first bottom-pixel electrode E11, the first blue LED B1, and the first top-pixel electrode E12 is equal to an interval between the driving substrate 1 and the package substrate 2, and a sum of the heights of the third bottom-pixel electrode E31, the red LED R, and the third top-pixel electrode E32 is equal to the interval between the driving substrate 1 and the package substrate 2.

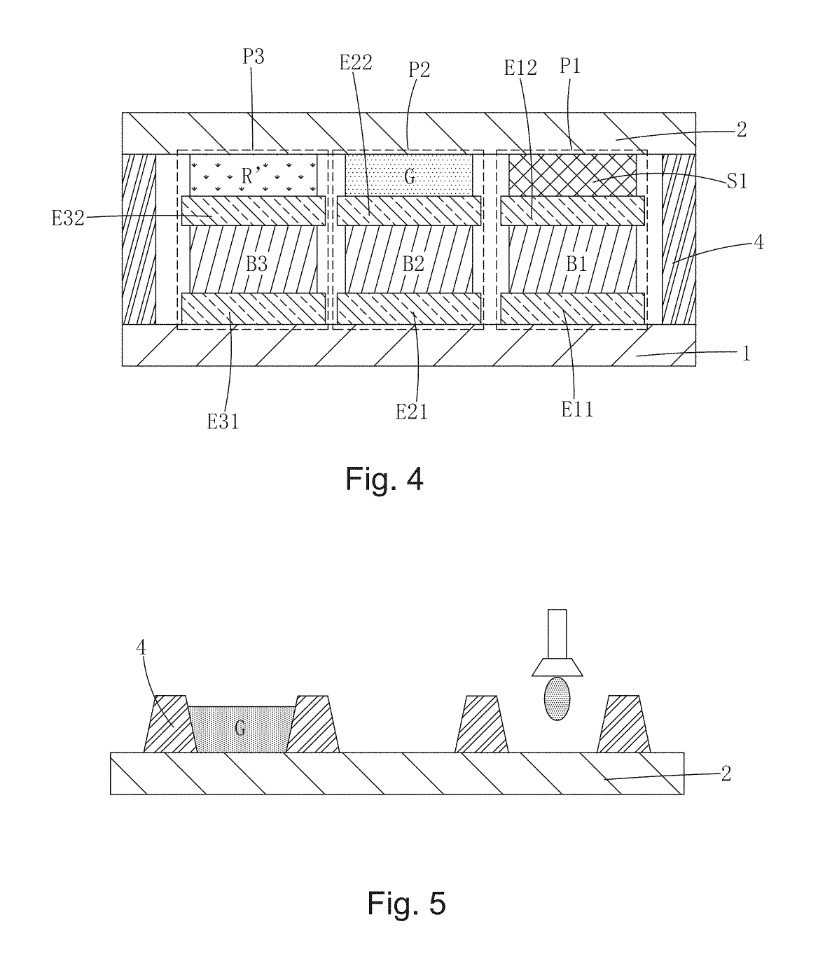

FIG. 4 shows a third embodiment of the Micro LED color display device of the present invention. The difference between the third embodiment and the first embodiment is: because the efficiency of the red LED R is often not high, and the red LED R inside the sub-pixel P3 interposed between the third bottom-pixel electrode E31 and the third top-pixel electrode E32 is replaced with a third blue LED B3 (which may emit light of a wavelength that is different from, or the same as one of, the wavelengths of the first and second blue LEDs B1, B2), and the second transparent spacer S2 interposed between the third top-pixel electrode E32 and the package substrate 2 is replaced with a red-color-conversion layer R′. With the red color light emitted by the third blue LED B3 to excite the red-color-conversion layer R′ instead of the red LED R to emit directly, the luminous efficiency of the red sub-pixel P3 is improved. The other structures are unchanged and are not described here repeatedly.

Furthermore, the red-color-conversion layer R′ is selected from red quantum dots.

The green-color-conversion layer G and the red-color-conversion layer R′ may be coated on the package substrate 2 by Slit Coating, Inkjet Printing (IJP), or thermal deposition and so on. Please Refer to FIG. 5, when the green-color-conversion layer G or the red-color-conversion layer R′ is coated between the pixel defining layers by the IJP method, the pixel defining layer may be used as the support 4.

As mentioned above, the Micro LED color display device of the invention, which uses the second blue LED with a short wavelength to excite the green-color-conversion layer to replace the green LED in the green sub-pixels, the second blue LED itself is more stable, the chromaticity of the green color is controlled by controlling the accuracy of the coating thickness of the green-color-conversion layer. The accuracy of the coating thickness is easily controlled than the specification of the green LED, hence, the chromaticity uniformity is better, the stability of the green color is easy to control, and the display quality is improved.

As mentioned above, those of ordinary skill in the art, without departing from the spirit and scope of the present invention, can make various kinds of modifications and variations to the present invention. Therefore, all such modifications and variations are intended to be included in the protection scope of the appended claims of the present invention.

What is claimed is:

1. A Micro LED color display device, comprising a driving substrate, a package substrate disposed opposite to the driving substrate, a plurality of blue sub-pixels, green sub-pixels, and red sub-pixels arranged in an array arrangement between the driving substrate and the package substrate, and a support disposed between the driving substrate and the package substrate; an LED is disposed in each of the sub-pixels;
the blue sub-pixels comprising a first bottom-pixel electrode disposed on the driving substrate, a first top-pixel electrode disposed opposite to the first bottom-pixel electrode, and a first blue LED interposed between the first bottom-pixel electrode and the first top-pixel electrode and emitting blue light of a first wavelength; the green sub-pixels comprising a second bottom-pixel electrode disposed on the driving substrate, a second top-pixel electrode disposed opposite to the second bottom-pixel electrode, a second blue LED interposed between the second bottom-pixel electrode and the second top-pixel electrode and emitting blue light of a second wavelength that is different from the first wavelength, and a green-color-conversion layer interposed between the second top-pixel electrode and the package substrate; the red sub-pixels comprising a third bottom-pixel electrode disposed on the driving substrate, a third top-pixel electrode disposed opposite to the third bottom-pixel electrode, and a LED interposed between the third bottom-pixel electrode and the third top-pixel electrode.

2. The Micro LED color display device according to claim 1, wherein in the red sub-pixel, the LED interposed between the third bottom-pixel electrode and the third top-pixel electrode is a red LED.

3. The Micro LED color display device according to claim 1, wherein in the red sub-pixels, the LED interposed between the third bottom-pixel electrode and the third top-pixel electrode is a third blue LED; the red sub-pixels further comprise a red-color-conversion layer interposed between the third top-pixel electrode and the package substrate.

4. The Micro LED color display device according to claim 2, wherein the blue sub-pixels further comprise a first transparent spacer disposed between the first top-pixel electrode and the package substrate, and the red sub-pixels further comprises a second transparent spacer disposed between the third top-pixel electrode and the package substrate.

5. The Micro LED color display device according to claim 3, wherein the blue sub-pixels further comprise a first transparent spacer disposed between the first top-pixel electrode and the package substrate.

6. The Micro LED color display device according to claim 1, wherein the green-color-conversion layer is selected from green quantum dots.

7. The Micro LED color display device according to claim 3, wherein the red-color-conversion layer is selected from red quantum dots.

8. The Micro LED color display device according to claim 4, wherein the first blue LED has a first height and the red LED has a second height, and wherein a height of the first transparent spacer and a height of the second transparent spacer are the same or different, a sum of the first height of the first blue LED and the height of the first transparent spacer and a sum of the second height of the red LED and the height of the second transparent spacer are the same.

9. The Micro LED color display device according to claim 2, wherein a height of the first top-pixel electrode and a height of the third top-pixel electrode are the same or different; a sum of heights of the first bottom-pixel electrode, the first blue LED, and the first top-pixel electrode is the same as an interval between the driving substrate and the package substrate; a sum of heights of the third bottom-pixel electrode, the red LED, and the third top-pixel electrode is the same as the interval between the driving substrate and the package substrate.

10. The Micro LED color display device according to claim 4, wherein the package substrate is made of a material selected among polyethylene terephthalate, polycarbonate, and glass;
the support is made of a material selected among organic photoresist and silicon ball;
the first transparent spacer and the second transparent spacer are each made of one of an organic transparent material and an inorganic transparent material; and
the first, second, and third top-pixel electrodes, and the first, second, and third bottom-pixel electrodes are each made of one of indium tin oxide and a conductive metal.

11. A Micro LED color display device, comprising a driving substrate, a package substrate disposed opposite to the driving substrate, a plurality of blue sub-pixels, green sub-pixels, and red sub-pixels arranged in an array arrangement between the driving substrate and the package substrate, and a support disposed between the driving substrate and the package substrate; an LED is disposed in each of the sub-pixels;
the blue sub-pixels comprising a first bottom-pixel electrode disposed on the driving substrate, a first top-pixel electrode disposed opposite to the first bottom-pixel electrode, and a first blue LED interposed between the first bottom-pixel electrode and the first top-pixel electrode and emitting blue light of a first wavelength; the green sub-pixels comprising a second bottom-pixel electrode disposed on the driving substrate, a second top-pixel electrode disposed opposite to the second bottom-pixel electrode, a second blue LED interposed between the second bottom-pixel electrode and the second top-pixel electrode and emitting blue light of a second wavelength that is different from the first wavelength, and a green-color-conversion layer interposed between the second top-pixel electrode and the package substrate; the red sub-pixels comprising a third bottom-pixel electrode disposed on the driving substrate, a third top-pixel electrode disposed opposite to the third bottom-pixel electrode, and a LED interposed between the third bottom-pixel electrode and the third top-pixel electrode;
wherein in the red sub-pixel, the LED interposed between the third bottom-pixel electrode and the third top-pixel electrode is a red LED;
wherein the blue sub-pixels further comprise a first transparent spacer disposed between the first top-pixel electrode and the package substrate, and the red sub-pixels further comprises a second transparent spacer disposed between the third top-pixel electrode and the package substrate;
wherein the green-color-conversion layer is selected from green quantum dots;
wherein the first blue LED has a first height and the red LED has a second height, and wherein a height of the first transparent spacer and a height of the second transparent spacer are the same or different, a sum of the first height of the first blue LED and the height of the first transparent spacer and a sum of the second height of the red LED and the height of the second transparent spacer are the same.

12. The Micro LED color display device according to claim 11, wherein a height of the first top-pixel electrode and a height of the third top-pixel electrode are the same or different; a sum of heights of the first bottom-pixel electrode, the first blue LED, and the first top-pixel electrode is the same as an interval between the driving substrate and the package substrate; a sum of heights of the third bottom-pixel electrode, the red LED, and the third top-pixel electrode is the same as the interval between the driving substrate and the package substrate.

13. The Micro LED color display device according to claim 4, wherein the package substrate is made of a material selected among polyethylene terephthalate, polycarbonate, and glass;
the support is made of a material selected among organic photoresist and silicon ball;
the first transparent spacer and the second transparent spacer are each made of one of an organic transparent material and an inorganic transparent material; and
the first, second, and third top-pixel electrodes, and the first, second, and third bottom-pixel electrodes are each made of one of indium tin oxide and a conductive metal.
